(19) United States
(12) Patent Application Publication
(10) Pub. No.: US 2025/0301918 A1
(43) Pub. Date: Sep. 25, 2025

(54) HALL EFFECT SENSORS

(71) Applicant: GlobalFoundries Singapore Pte. Ltd., Singapore (SG)

(72) Inventors: Ping ZHENG, Singapore (SG); Eng Huat TOH, Singapore (SG); Yongshun SUN, Singapore (SG)

(21) Appl. No.: 18/613,788

(22) Filed: Mar. 22, 2024

(51) Int. Cl. H10N 52/00; G01R 15/20; G01R 33/07; H10N 52/01

(52) U.S. Cl. CPC H10N 52/101; G01R 15/202; G01R 33/07; H10N 52/01

(57) ABSTRACT

The present disclosure relates to semiconductor structures and, more particularly, to Hall effect sensors and methods of manufacture. The structure includes: a semiconductor material; a buried isolation layer below the semiconductor material; a deep trench structure having conductive material and within the semiconductor material and contacting the buried isolation layer; a plurality of shallower trench structures having the conductive material and partially within the semiconductor material and remote from the buried isolation layer; and a doped region within the semiconductor material adjacent to the plurality of shallower trench structures.

### BACKGROUND

The present disclosure relates to semiconductor structures and, more particularly, to Hall effect sensors and methods of manufacture.

The Hall effect is the production of a potential difference (the Hall voltage) across an electrical conductor that is transverse to an electric current in the conductor and to an applied magnetic field perpendicular to the current. That is, a Hall effect is when a magnetic field is applied at right angles to a current flow in a thin film where an electric field is generated, which is mutually perpendicular to the current and the magnetic field and which is directly proportional to the product of the current density and the magnetic induction.

Hall effect sensors are used for picking up on the voltage induced on the conductor by the magnetic field. The output of the Hall effect sensors will be proportional to the magnetic field intensity and direction, or it can be binary, based on electronics embedded in the sensing packaging.

### SUMMARY

In an aspect of the disclosure, a structure comprises: a semiconductor material; a buried isolation layer below the semiconductor material; a deep trench structure comprising conductive material and within the semiconductor material and contacting the buried isolation layer; a plurality of shallower trench structures comprising the conductive material and partially within the semiconductor material and remote from the buried isolation layer; and a doped region within the semiconductor material adjacent to the plurality of shallower trench structures.

In an aspect of the disclosure, a structure comprises: a first contact having a first depth in a semiconductor substrate; a plurality of second contacts having a second depth in the semiconductor substrate and being adjacent to the first contact; a third contact having a third depth in the semiconductor substrate and being shallower than the first depth and the second depth; and a buried isolation structure within the semiconductor substrate and contacting the first contact.

In an aspect of the disclosure, a method comprises: forming a semiconductor material; forming a buried isolation layer below the semiconductor material; forming a deep trench structure comprising conductive material and extending within the semiconductor material and contacting the buried isolation layer; forming a plurality of shallower trench structures comprising the conductive material and extending partially within the semiconductor material and remote from the buried isolation layer; and forming a doped region within the semiconductor material adjacent to the plurality of shallower trench structures.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a cross-sectional view of a Hall effect sensor and respective fabrication processes along line A-A of FIG. 1C in accordance with aspects of the present disclosure.

FIG. 1B shows another cross-sectional view of the Hall effect sensor and respective fabrication processes along line B-B of FIG. 1C in accordance with aspects of the present disclosure.

FIGS. 1C and 1D show a top view of the Hall effect sensor shown in FIGS. 1A and 1B in accordance with aspects of the present disclosure.

FIGS. 2A and 2B show a top view of a Hall effect sensor in accordance with additional aspects of the present disclosure.

FIGS. 3A and 3B show a top view of a Hall effect sensor in accordance with further aspects of the present disclosure.

FIGS. 4A-4D show fabrication processes of the Hall effect sensor along the cross-sectional view of FIG. 1A.

### DETAILED DESCRIPTION

The present disclosure relates to semiconductor structures and, more particularly, to Hall effect sensors and methods of manufacture. More specifically, the present disclosure relates to vertical Hall effect sensors with deep trench structures. In embodiments, the deep trench structures may be provided in a thick epitaxial semiconductor material. Advantageously, the Hall effect sensors are of compact size and free from inter-diffusion of implantation. Moreover, the Hall effect sensors can be manufactured without concern to current limitations of implant tools, e.g., which have implant capabilities to a depth approximately 3 μm to 4 μm.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

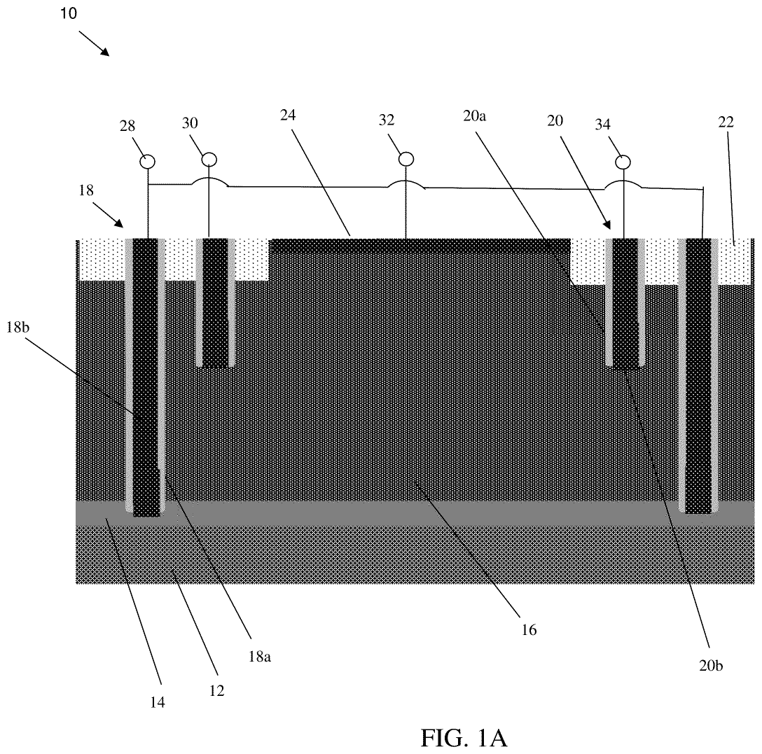

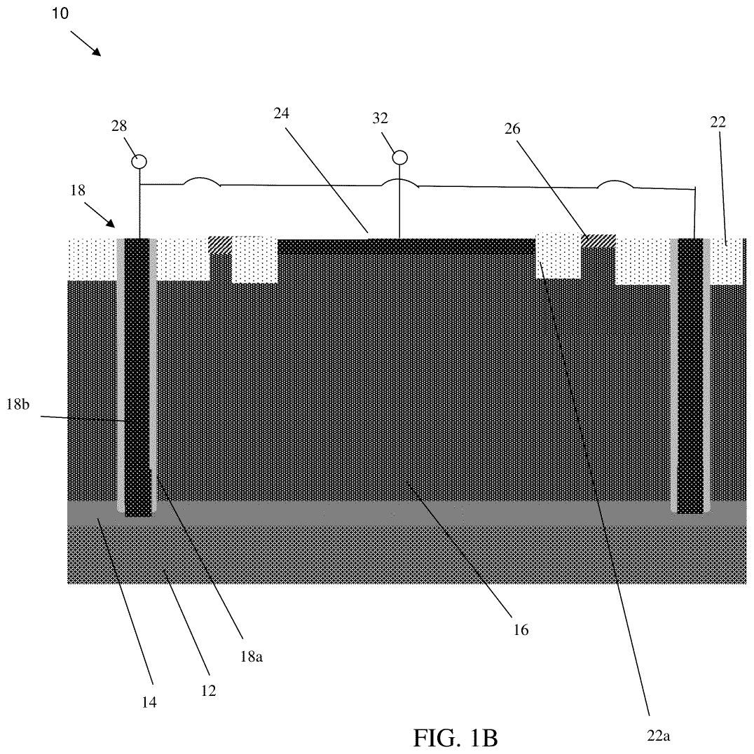

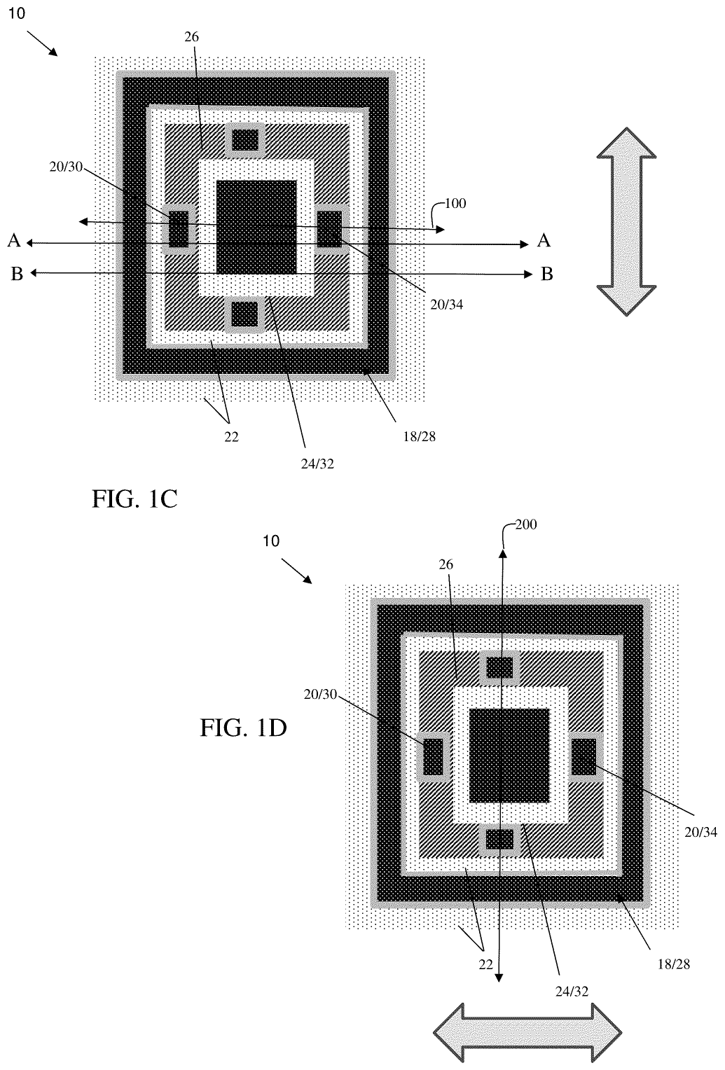

FIG. 1A shows a cross-sectional view of a Hall effect sensor and respective fabrication processes along line A-A of FIG. 1C in accordance with aspects of the present disclosure. FIG. 1B shows another cross-sectional view of the same Hall effect sensor and respective fabrication processes along line B-B of FIG. 1C. In embodiments, the Hall effect sensor 10 comprises a terminal 28 comprising a deep trench structure 18 and terminals 30, 34 comprising shallower trench structures 20, each of which extend within a semiconductor material 16. In embodiments, the deep trench structure 18 extends to and contacts a buried isolation structure 14 (e.g., buried N+ semiconductor layer) within a semiconductor substrate 12.

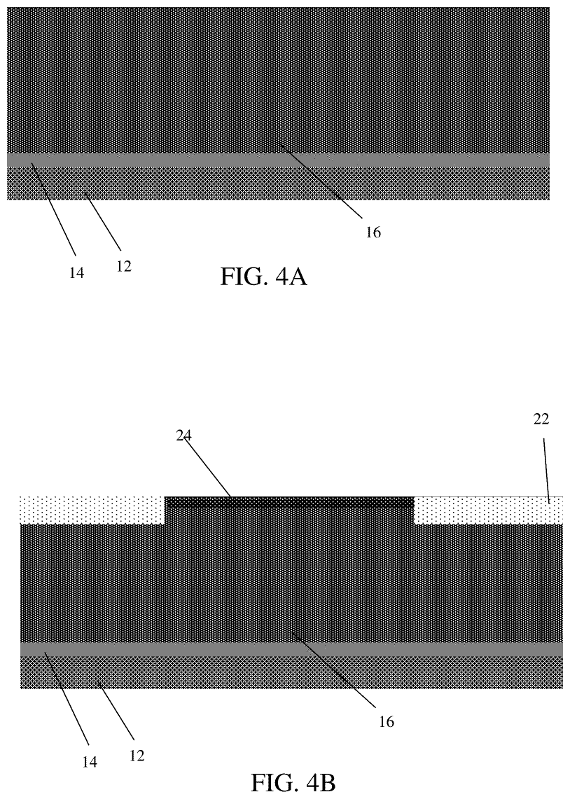

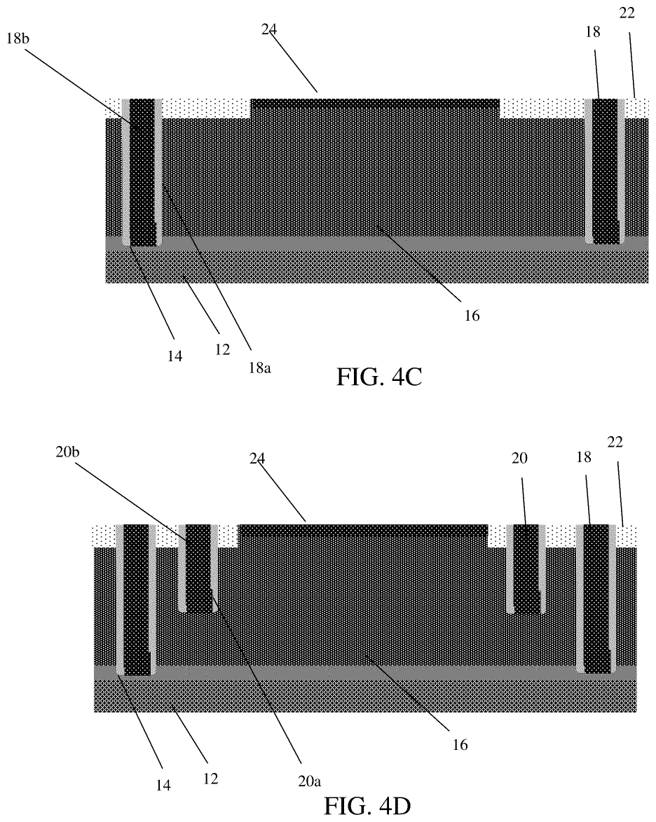

The semiconductor substrate 12 may comprise a p-type semiconductor substrate as is known in the art. The semiconductor substrate 12 may be composed of any suitable material including, but not limited to, Si, SiGe, SiGeC, SiC, GaAs, InAs, InP, and other III/V or II/VI compound semiconductors. In preferred embodiments, the semiconductor substrate 12 may comprise any suitable single crystallographic orientation (e.g., a <100>, <110>, <111>, or <001> crystallographic orientation). The buried isolation structure 14 may be a buried N+ semiconductor layer within the semiconductor substrate 12 formed by an ion implantation process as described with respect to FIG. 4A.

Still referring to FIG. 1A, an N− semiconductor material 16 may be provided over the buried N+ semiconductor layer 14. In embodiments, the N− semiconductor material 16 may be epitaxial grown semiconductor material with an in-situ n-type dopant, e.g., arsenic. In embodiments, the N− semiconductor material 16 may be composed of the same semiconductor material as the semiconductor substrate 12. In further embodiments, the N− semiconductor material 16 may have a thickness of approximately 6 μm or 7 μm, or greater (which may exceed a depth limit of current implant tools).

FIGS. 1A and 1B further show a deep trench structure 18 and shallower trench structures 20. The deep trench structure 18 physically and electrically connects to the buried N+ semiconductor layer 14. Accordingly, the deep trench structure 18 extends through the N− semiconductor material 16 to contact the buried N+ semiconductor layer 14. The shallower trench structures 20 extend partially within the N− semiconductor material 16 (e.g., will not physically contact to the buried N+ semiconductor layer 14). The buried N+ semiconductor layer 14 may provide isolation for doped regions 24, 26.

The deep trench structure 18 and the shallower trench structures 20 may be separated or electrically isolated from one another by a shallow trench isolation structure 22. The deep trench structure 18 and the shallower trench structure 20 may be formed by conventional lithography, etching and deposition processes as described with respect to FIGS. 4C and 4D. The shallow trench isolation structure 22 may be formed by conventional lithography, etching and deposition processes as described with respect to FIG. 4B. The shallow trench isolation structure 22 may be composed of insulator material, e.g., SiO₂.

In embodiments, the deep trench structure 18 and the shallower trench structures 20 may be contacts comprising conductive material and an insulator liner material. For example, the deep trench structure 18 includes an insulative liner 18a and conductive material 18b. Similarly, the shallower trench structures 20 include an insulative liner 20a and conductive material 20b. In embodiments, the liner material may be any insulator material lining the sidewalls of a trench formed in the N− semiconductor material 16. For example, the liner material may be an oxide material (e.g., SiO₂) or a nitride material (e.g., SiN); although other materials and combinations thereof are also contemplated herein. In this way, the conductive material will be isolated from the N− semiconductor material 16. The conductive material may be a metal, metal alloy or doped polysilicon, as examples, which contact terminals 28, 30, 34. In embodiments, the dopant of the conductive material may be the same dopant type with a different dopant concentration, e.g., higher, as the dopant used for the N− semiconductor material 16.

FIGS. 1A and 1B further show doped region 24. In embodiments, the doped region 24 may be an N+ doped region formed by an ion implantation process as described with respect to FIG. 4B. The N+ doped region 24 may be a contact to terminal 32.

FIG. 1B shows doped region 26. The doped region 26 may be a P+ region formed adjacent to the doped region 24, the deep trench structure 18 and the shallower trench structure 20 (see, e.g., FIGS. 1C and 1D). The doped region 26 may provide additional isolation to the doped region 24. The doped region 26 may also be separated from the doped region 24 by the shallow trench structure(s) 22a and may be formed by an ion implantation process as is known in the art and further described herein. In embodiments, the doped regions 24, 26, the deep trench structure 18 and the shallower trench structure 20 are free from the implant tool limitations for terminal formation.

FIGS. 1C and 1D are top views of the Hall effect sensor shown in FIGS. 1A and 1B. As shown in FIGS. 1C and 1D, for example, the shallow trench isolation structures 22 surround and isolate the doped regions 24, 26, the deep trench structure 18 and the shallower trench structures 20. The shallow trench isolation structures 22 also isolate the deep trench structure 18 from the shallower trench structure 20. In addition, the deep trench structure 18 surrounds the shallower trench structures 20, the N+ doped region 24 and the P+ doped region 26. The P+ doped region 26 isolates the N+ doped region 24. The shallower trench structures 20 may act as contacts to terminals 30, 34, and may be provided on each side of the N+ doped region 24 (connecting to terminal 32), within the P-doped region 26, for example. Accordingly, four (4) shallower trench structures 20 may be provided to sense a magnetic field in both the horizontal and vertical direction.

In the orientation of FIG. 1C, the Hall effect sensor 10 may detect an external magnetic field in the vertical direction as shown by the vertical arrow, whereas, in the orientation of FIG. 1D, the Hall effect sensor 10 may detect an external magnetic field in the horizontal direction as shown by the horizontal arrow. More specifically, the Hall effect sensor 10 in FIG. 1C may pick up the voltage induced on the terminals 30, 32, 34 in the horizontal orientation (shown by arrow 100) by the external magnetic field in the vertical direction (perpendicular magnetic field) as shown by the external vertical arrow. On the other hand, the Hall effect sensor 10 in FIG. 1D, may pick up the voltage induced on the terminals 30, 32, 34 in the vertical orientation (shown by arrow 200) by the external magnetic field in the horizontal direction (perpendicular magnetic field) as shown by the external horizontal arrow. The output of the Hall effect sensor 10 will be proportional to the magnetic field intensity and direction.

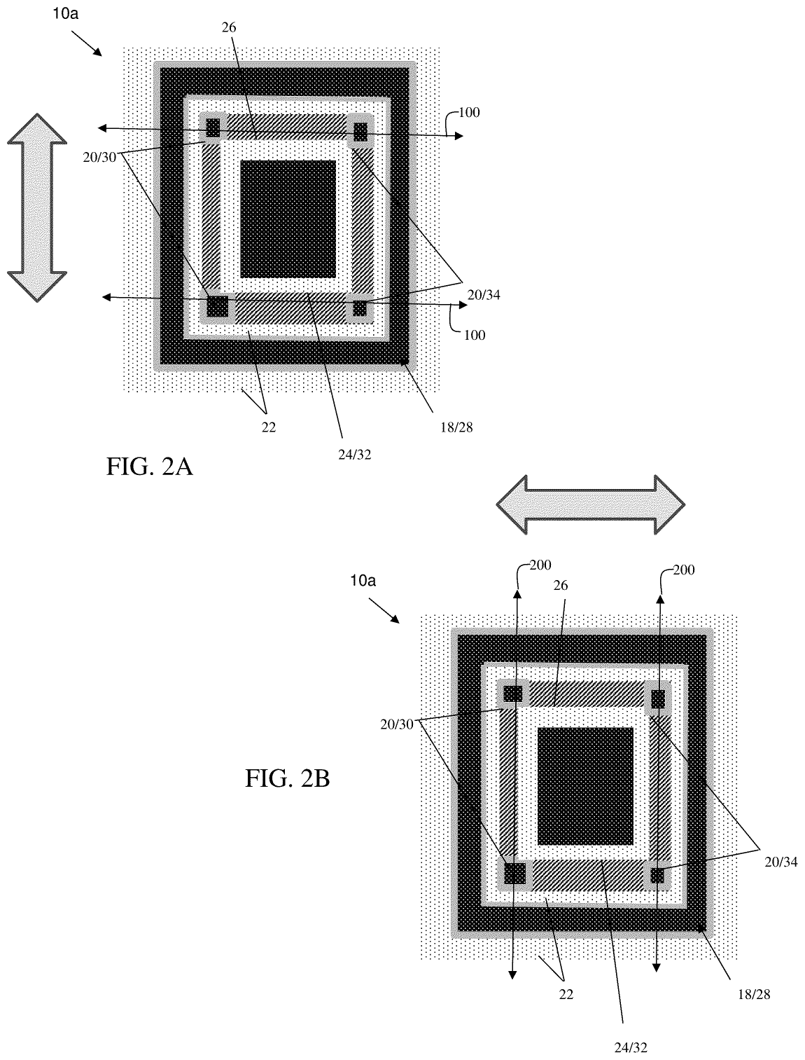

FIGS. 2A and 2B show a top view of a Hall effect sensor 10a in accordance with additional aspects of the present disclosure. In the Hall effect sensor 10a shown in FIGS. 2A and 2B, the shallower trench structures 20, e.g., terminals 30, 34, are provided at each of the corners of the N+ doped region 24 (e.g., terminal 32). Accordingly, four (4) shallower trench structures 22 may be provided to sense a magnetic field in both the horizontal and vertical direction. It should also be understood by those of skill in the art, that the terminals 30, 34 may also be on the sides, resulting in three sets of terminals which provide further sensitivity. The remaining features of the Hall effect sensor 10a are similar in structure and function to the Hall effect sensor 10 shown in FIGS. 1A-1D.

In the orientation of FIG. 2A, the Hall effect sensor 10a may detect an external magnetic field in the vertical direction as shown by the vertical arrow by two sets of terminals 30, 34 in the horizontal direction (shown by arrows 100). In the orientation of FIG. 2B, the Hall effect sensor 10a may detect an external magnetic field in the horizontal direction as shown by the horizontal arrow by two sets of terminals 30, 34 in the vertical direction (shown by arrows 200).

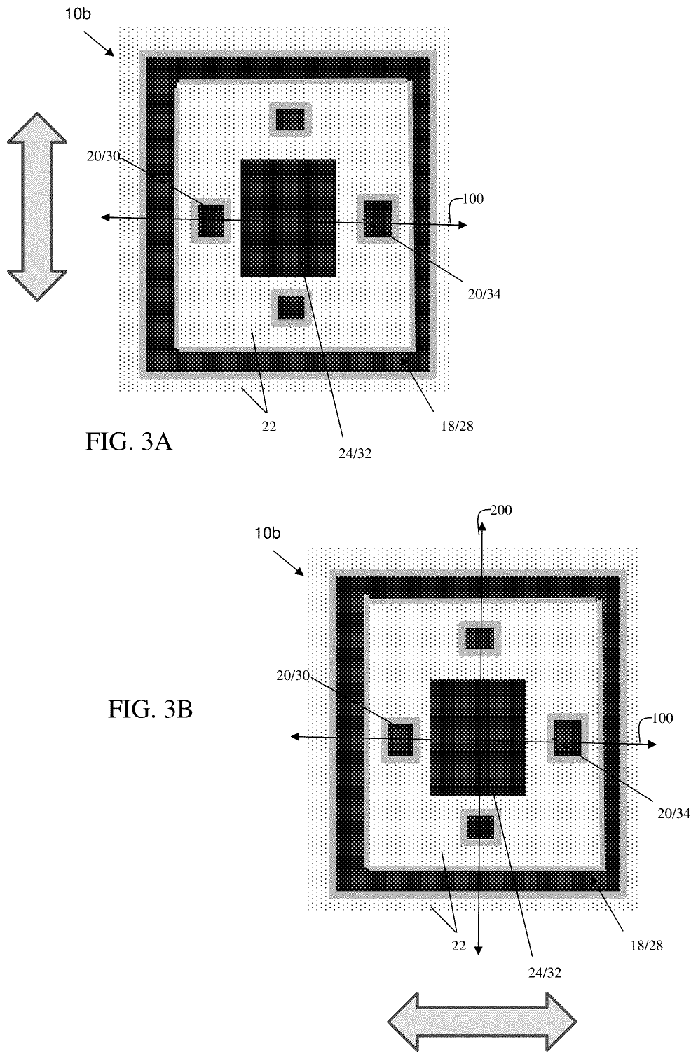

FIGS. 3A and 3B show a top view of a Hall effect sensor 10b in accordance with additional aspects of the present disclosure. In the Hall effect sensor 10b shown in FIGS. 3A and 3B, the shallower trench structures 20, e.g., terminals 30, 34, may be surrounded by the shallow trench isolation structure 22. In this way, the P+ doped region may be eliminated. The remaining features of the Hall effect sensor 10b are similar in structure and function to the Hall effect sensor 10 shown in FIGS. 1A-1D. It should also be understood by those of skill in the art that the shallower trench structures 20, e.g., terminals 30, 34, may be provided at the corners (as shown in FIGS. 2A and 2B) or in combination on the sides and corners.

FIGS. 4A-4C show fabrication processes of the Hall effect sensor along the cross-sectional view of FIG. 1A. FIG. 4A shows the p-type semiconductor substrate 12 with the buried N+ semiconductor layer 14 and N− semiconductor material 16. The buried N+ semiconductor layer 14 has a higher doping concentration than the N− semiconductor material 16. As a non-limiting example, the doping concentration of the N+ semiconductor layer 14 may be 1E18 or higher; although other doping concentrations are also contemplated herein.

In embodiments, the buried N+ semiconductor layer 14 is formed by an ion implantation process in the p-type semiconductor substrate 12. For example, the buried N+ semiconductor layer 14 may be formed by introducing a concentration of an n-type dopant in the p-type semiconductor material 12. In embodiments, a patterned implantation mask may be used to define selected areas exposed for the implantation. As is known, the implantation mask used to select the exposed area for forming the buried N+ semiconductor layer 14 may be stripped after implantation. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions. The buried N+ semiconductor layer 14 may be doped with n-type dopants, e.g., Arsenic (As), Phosphorus (P) and Antimony (Sb), among other suitable examples.

The N− semiconductor material 16 may be epitaxially grown on the N+ buried semiconductor layer 14. As with each of the semiconductor materials, the N-semiconductor material 16 may be composed of any suitable material including, but not limited to, Si, SiGe, SiGeC, SiC, GaAs, InAs, InP, and other III/V or II/VI compound semiconductors. Examples of various epitaxial growth processes that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth process can be performed utilizing any well-known precursor gas or gas mixture. Carrier gases like hydrogen, nitrogen, helium and argon can be used. A dopant (n-type) may be added to the precursor gas or gas mixture for an in-situ doping process. The N− semiconductor material 16 may be grown to a thickness of about 6 μm or greater, as an example.

FIG. 4B shows the formation of the shallow trench isolation structures 22 and the doped region 24. The shallow trench isolation structures 22 can be formed by conventional lithography, etching and deposition methods known to those of skill in the art. For example, a resist formed over the N− semiconductor material 16 is exposed to energy (light) and developed utilizing a conventional resist developer to form a pattern (opening). An etching process with a selective chemistry, e.g., reactive ion etching (RIE), will be used to transfer the pattern from the patterned photoresist to the N− semiconductor material 16 to form one or more trenches in the N− semiconductor material 16. Following the resist removal by a conventional oxygen ashing process or other known stripants, the insulator material can be deposited by any conventional deposition processes, e.g., chemical vapor deposition (CVD) processes. Any residual material on the surface of the N− semiconductor material 16 can be removed by conventional chemical mechanical polishing (CMP) or etch back processes.

The doped region 24 may be formed by an ion implantation process as already described herein. As the doped region 24 is a shallow doped region, the implantation process will not exceed the limitations of the implant tool. The doped region may be doped by an n-type dopant, e.g., Arsenic (As), Phosphorus (P) and Sb, among other suitable examples. The dopant concentration may be, for example, 1E19 or greater, as an example. It should also be understood by those of ordinary skill in the art that the doped region 24 may be formed by a similar dopant process, with a p-type dopant, e.g., boron.

FIG. 4C shows the formation of the deep trench structure 18. The deep trench structure 18 may be formed by conventional lithography, etching and deposition methods known to those of skill in the art. For example, in the etching process (e.g., RIE), a trench will be formed through the N− semiconductor material 16 and into the buried N+ semiconductor layer 14. Following the resist removal by a conventional oxygen ashing process or other known stripants, insulator material can be deposited on sidewalls of the trench, followed by an anisotropic etching process to remove the insulator material from a bottom of the trench to expose the buried N+ semiconductor layer 14. A conductive material is then deposited within the remaining portions of the trench, which will directly contact the buried N+ semiconductor layer 14. In embodiments, the conductive material may be polysilicon material doped with an n-type dopant. In embodiments, the n-type dopant may be at a higher concentration than the N− semiconductor material 16, e.g., 1E19 or higher. Any residual material on the N− semiconductor material 16 may be removed by a conventional CMP or etch back processes.

FIG. 4D shows the formation of the shallower trench structures 20. The shallower trench structures 20 may be formed by conventional lithography, etching and deposition methods known to those of skill in the art. For example, in the etching process (e.g., RIE), a trench will be formed partially through the N− semiconductor material 16 (e.g., not extending to or exposing the buried N+ semiconductor layer 14). Following the resist removal by a conventional oxygen ashing process or other known stripants, insulator material can be deposited on sidewalls of the trench, followed by an anisotropic etching process to remove the insulator material from a bottom of the trench. A conductive material is then deposited within the remaining portions of the trench, which will be remotely positioned from and not contact the buried N+ semiconductor layer 14. In embodiments, the conductive material may be polysilicon material doped with an n-type dopant. As previously noted, in embodiments, the n-type dopant may be at a higher concentration than the N− semiconductor material 16, e.g., 1E19 or higher. Any residual material on the N− semiconductor material 16 may be removed by a conventional CMP process or etch back processes.

Referring to FIGS. 1A-1D, the terminals 28, 30, 32, 34 may be wiring structures and/or via interconnects connecting to the respective doped region 24, deep trench structure 18 and shallower trench structures 20 (which may also be considered terminals). The terminals 28, 30, 32, 34 may be formed by conventional lithography, etching and deposition methods known to those of skill in the art such that no further explanation is required for a complete understanding of the present disclosure.

Prior to forming the terminals 28, 30, 32, 34, the conductive material 18b, 20b, and doped region 24 may undergo a silicide process. As should be understood by those of skill in the art, the silicide process begins with deposition of a thin transition metal layer, e.g., nickel, cobalt or titanium, over the semiconductor material, e.g., conductive material 18b, 20b, and doped region 24. The remaining regions may include a masking material (e.g., nitride) to prevent the formation of the transition metal on such regions. After deposition of the material, the structure is heated allowing the transition metal to react with exposed silicon (or other semiconductor material as described herein) forming a low-resistance transition metal silicide. Following the reaction, any remaining transition metal is removed by chemical etching, leaving silicide contacts. It should be understood by those of skill in the art that silicide contacts will not be required on the structures composed of a metal material.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor material;
a buried isolation layer below the semiconductor material;
a deep trench structure comprising conductive material and within the semiconductor material and contacting the buried isolation layer;
a plurality of shallower trench structures comprising the conductive material and partially within the semiconductor material and remote from the buried isolation layer; and
a doped region within the semiconductor material adjacent to the plurality of shallower trench structures.

2. The structure of claim 1, wherein the deep trench structure and the plurality of shallower trench structures comprise an insulator liner which isolates the conductive material from the semiconductor material.

3. The structure of claim 2, wherein the conductive material comprises doped polysilicon material.

4. The structure of claim 3, wherein the doped polysilicon material comprises a same dopant type as the buried isolation layer and the semiconductor material.

5. The structure of claim 4, wherein the dopant type is n-type dopant and a concentration of the dopant type of the polysilicon material is greater than a concentration of the dopant type of the semiconductor material.

6. The structure of claim 2, further comprising shallow trench structures which isolate the deep trench structure from the plurality of shallower trench structures.

7. The structure of claim 1, wherein each of the plurality of shallower trench structures are on sides of the doped region.

8. The structure of claim 1, wherein each of the plurality of shallower trench structures are on corners of the doped region.

9. The structure of claim 1, wherein the plurality of shallower trench structures are isolated within a shallow trench structure which surrounds the doped region.

10. The structure of claim 1, wherein the plurality of shallower trench structures are isolated within a second doped region of opposite dopant type than the doped region.

11. The structure of claim 1, further comprising a second doped region which surrounds the doped region, wherein the second doped region comprises opposite dopant type than the doped region.

12. A structure comprises:
a first contact having a first depth in a semiconductor substrate;
a plurality of second contacts having a second depth in the semiconductor substrate and being adjacent to the first contact;
a third contact having a third depth in the semiconductor substrate and being shallower than the first depth and the second depth; and
a buried isolation structure within the semiconductor substrate which contacts the first contact.

13. The structure of claim 12, wherein the second depth is shallower than the first depth and the second depth is remotely positioned from the buried isolation structure.

14. The structure of claim 13, wherein the first contact and the plurality of second contacts comprise conductive material and lined with an insulator material, the insulator material isolates the conductive material from the semiconductor substrate.

15. The structure of claim 14, wherein the conductive material comprises doped polysilicon material.

16. The structure of claim 15, wherein the first depth is to the buried isolation structure comprises a same dopant type as the doped polysilicon material and the semiconductor substrate.

17. The structure of claim 12, wherein the plurality of second contacts are horizontally and vertically positioned with respect to each one at opposing sides of the third contact.

18. The structure of claim 12, wherein the plurality of second contacts are horizontally and vertically positioned with respect to each one at corners of the third contact.

19. The structure of claim 12, wherein the plurality of second contacts and the first contact are isolated from one another by a shallow trench isolation structure.

20. A method comprising:
forming a semiconductor material;
forming a buried isolation layer below the semiconductor material;
forming a deep trench structure comprising conductive material and extending within the semiconductor material and contacting the buried isolation layer;
forming a plurality of shallower trench structures comprising the conductive material and extending partially within the semiconductor material and remote from the buried isolation layer; and
forming a doped region within the semiconductor material adjacent to the plurality of shallower trench structures.
